(19) United States
(12) Patent Application Publication
(10) Pub. No.: US 2010/0128237 A1
(43) Pub. Date: May 27, 2010

(54) DRIVING APPARATUS, EXPOSURE APPARATUS, AND DEVICE MANUFACTURING METHOD

(75) Inventors: Tomohiro Okamoto, Utsunomiya-shi (JP); Kenichi Imanishi, Utsunomiya-shi (JP)

Correspondence Address: ROSSI, KIMMS & McDOWELL LLP., 20609 Gordon Park Square, Suite 150, Ashburn, VA, 20147, US

(73) Assignee: CANON KABUSHIKI KAISHA, Tokyo (JP)

(21) Appl. No.: 12/623,010

(22) Filed: Nov. 20, 2009

(30) Foreign Application Priority Data
Nov. 21, 2008 (JP) 2008-298788

(51) Int. Cl. G03F 7/207; F16B 39/36; G03B 27/54

(52) U.S. Cl. 355/55; 411/265; 355/77

(57) ABSTRACT

A driving apparatus of the present invention is a driving apparatus which adjusts a position of a member to be driven. The driving apparatus comprises a driving member connected with the member to be driven and made of an elastic member, a female screw provided so as to penetrate the driving member, and a taper-shaped male screw configured to be screwed into the female screw. The driving member is provided with a cutting portion which penetrates in an axis direction of the female screw so that an inner circumference of the female screw is discontinuous, and the driving member is configured to move in an axis direction of the male screw in a state where the male screw is screwed into the female screw to displace the member to be driven in a direction orthogonal to the axis direction of the male screw.

### BACKGROUND OF THE INVENTION

1. Field of the Invention

The present invention relates to a driving apparatus and more particularly to a driving apparatus which adjusts a position of a member to be driven using a taper-shaped male screw.

2. Description of the Related Art

Conventionally, as a method of positioning an optical element of an optical barrel at a predetermined area, various kinds of methods have been well known. For example, there is a throw-in type method of processing parts including a lens with a predetermined accuracy and assembling the parts to align an optical axis with a reference center. Further, there is a ball pushing type method of performing an adjustment cutting of an outer diameter of a lens and in an optical axis direction while providing a cutting stock at a lens assembling portion, an adjustment assembling type method of assembling it while performing an eccentric adjustment at an adjustment side and a side to be adjusted, or the like.

In an exposure apparatus used for manufacturing a semiconductor device, a reduced projection is performed by a projection optical system between an original plate and a substrate. In the projection optical system, each optical element is positioned with high accuracy at the time of assembling the projection optical system so that aberrations can be limited in a permissible range. Therefore, for example, as disclosed in Japanese Patent Laid-open No. 2001-124968, an assembling method by a cell structure having a positioning reference part which has a superior cutting workability has been used.

Conventionally, as a method of performing a positioning adjustment of the optical element, there has been a method of using an adjustment screw or using a combination of the adjustment screw and an elastic member. When using the adjustment screw, the displacement in an axis direction along with the rotation of the screw is generally used for the adjustment. As a screw adjusting method different from the above method, as disclosed in Japanese Patent Laid-open No. 2000-019380 and Japanese Patent Laid-open No. 2001-208946, there is a method of adjusting a position using the change of the diameter of the taper portion which is separately provided from the screw portion, along with the rotation of the screw.

In Japanese Patent Laid-open No. 2000-120679, an adjustment method of using a change of screw diameter along with the screw rotation of a taper screw which is integrated by a taper and a screw is disclosed. Further, in Japanese Patent Laid-open No. 2001-343575, a method of adjusting a position of an optical element using a piezoelectric element is disclosed.

An optical barrel is constituted by a plurality of optical elements stacked along an optical axis direction. In order to improve the degree of adjustment freedom of an optical performance, positions of the plurality of optical elements need to be adjusted. Therefore, in particular, an adjusting apparatus whose size is thin in the optical axis direction is required.

In a method disclosed in Japanese Patent Laid-open No. 2001-124968, a barrel needs to be taken apart for adjustment after the barrel is assembled to measure the aberrations. Therefore, it takes a long time required for the position adjustment.

In methods disclosed in Japanese Patent Laid-open No. 2000-019380 and Japanese Patent Laid-open No. 2001-208946, because a taper portion and a screw portion are separated, the sizes of them in an axis direction are large, and the taper portion is required for contacting a member to be adjusted with reference to the screw portion. Therefore, the control in assembling is complicated. Further, because the force applied to the taper portion is a moment at the screw portion, the accuracy may be deteriorated by the influence of a backlash of the screw portion.

In Japanese Patent Laid-open No. 2000-120679, a taper screw whose screw portion has a taper slope is disclosed. However, in Japanese Patent Laid-open No. 2000-120679, since a screw hole of the screw portion is not penetrated, a contact area in an axis direction changes along with the rotation of the taper screw, and a bad influence is given to adjustment accuracy (linearity) or other components. In order to increase an adjustment amount by the taper screw and the elastic member, an inner circumference of the screw hole needs to be easily deformed. However, as disclosed in Japanese Patent Laid-open No. 2000-120679, when the screw hole is continuous in a whole circumference with respect to a center axis, it is difficult to increase the adjustment amount because an elastic deformation area is in the vicinity of the screw hole.

In Japanese Patent Laid-open No. 2001-343575, a configuration of driving an optical element using a piezoelectric element is disclosed. However, when using the piezoelectric element, a controller which electrically controls the piezoelectric element is necessary and a size of a driving apparatus is larger.

### BRIEF SUMMARY OF THE INVENTION

The present invention provides a small-sized driving apparatus capable of adjusting a position of a member to be driven with high accuracy.

A driving apparatus as one aspect of the present invention is a driving apparatus which adjusts a position of a member to be driven. The driving apparatus comprises a driving member connected with the member to be driven and made of an elastic member, a female screw provided so as to penetrate the driving member, and a taper-shaped male screw configured to be screwed into the female screw. The driving member is provided with a cutting portion which penetrates in an axis direction of the female screw so that an inner circumference of the female screw is discontinuous. The driving member is configured to move in an axis direction of the male screw in a state where the male screw is screwed into the female screw to displace the member to be driven in a direction orthogonal to the axis direction of the male screw.

An exposure apparatus as another aspect of the present invention is an exposure apparatus which exposes a pattern on an original plate onto a substrate. The exposure apparatus comprises an illumination optical system configured to illuminate the original plate by using light from a light source, and a projection optical system configured to project the pattern on the original plate onto the substrate. The projection optical system includes an optical element and a driving apparatus configured to adjust a position of the optical element in an optical axis direction. The driving apparatus includes a driving member made of an elastic member, a female screw provided so as to penetrate the driving member, and a taper-shaped male screw configured to be screwed into the female screw. The driving member is provided with a cutting portion which penetrates in an axis direction of the female screw so that an inner circumference of the female screw is discontinuous. The driving member is configured to move in an axis direction of the male screw in a state where the male screw is screwed into the female screw to displace the optical element in a direction orthogonal to the axis direction of the male screw.

A device manufacturing method as another aspect of the present invention comprises the steps of exposing a substrate using the exposure apparatus and developing the exposed substrate.

Further features and aspects of the present invention will become apparent from the following description of exemplary embodiments with reference to the attached drawings.

### BRIEF DESCRIPTION OF THE DRAWINGS

FIGS. 1A and 1B are schematic configuration diagrams of a driving apparatus in Embodiment 1.

FIGS. 2A and 2B are schematic configuration diagrams of a driving apparatus in Embodiment 2.

FIGS. 3A to 3C are diagrams showing a relationship between diameters of a taper screw and a female screw in a driving apparatus of Embodiment 2.

FIG. 4 is a schematic configuration diagram of a driving apparatus in Embodiment 3.

FIG. 5 is a schematic configuration diagram of a driving apparatus in Embodiment 4.

FIG. 6 is a schematic configuration diagram of another driving apparatus in Embodiment 4.

FIG. 7 is a schematic configuration diagram of a driving apparatus in Embodiment 5.

FIG. 8 is a schematic configuration diagram of a driving apparatus in Embodiment 6.

FIGS. 9A and 9B are schematic configuration diagrams of an optical element adjusting apparatus in the present embodiment.

FIG. 10 is a cross-sectional diagram of an optical barrel which is provided with a plurality of optical element adjusting apparatuses in the present embodiment.

FIG. 11 is a schematic configuration diagram of an exposure apparatus in the present embodiment.

### DETAILED DESCRIPTION OF THE PREFERRED EMBODIMENTS

Exemplary embodiments of the present invention will be described below with reference to the accompanied drawings. In each of the drawings, the same elements will be denoted by the same reference numerals and the duplicate descriptions thereof will be omitted.

### Embodiment 1

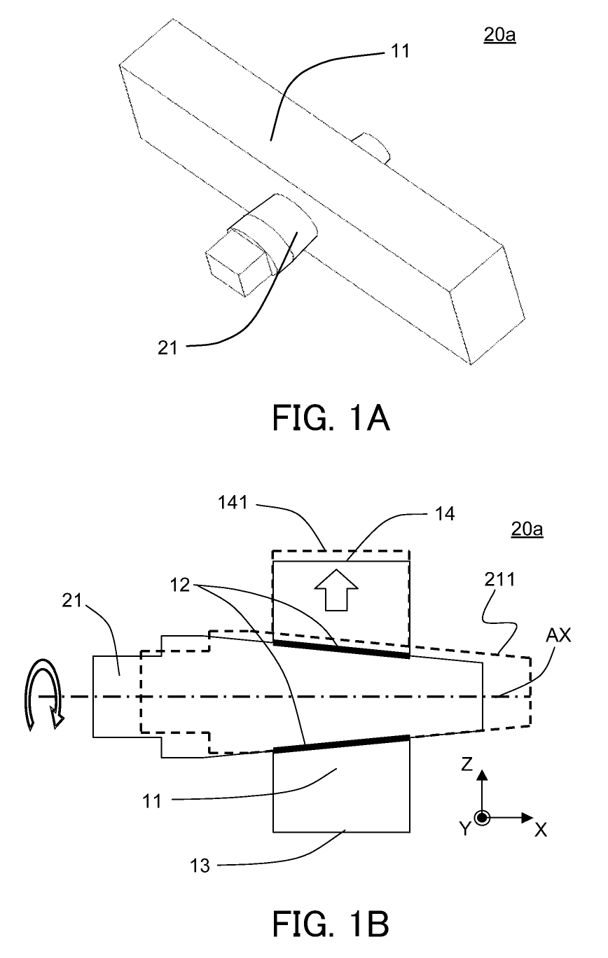

First, Embodiment 1 of the present invention will be described. FIG. 1 is a schematic configuration diagram of a driving apparatus in the present embodiment.

Specifically, FIG. 1A is a perspective view of a driving apparatus 20a, and FIG. 1B is a cross-sectional view obtained by cutting in a plane of a z direction that is a driving direction of the driving apparatus 20a and an x direction that is an axis direction of a taper screw 21 at the center of an axis of the taper screw 21. The driving apparatus 20a of the present embodiment is a driving apparatus which adjusts a position of a member to be driven.

In FIG. 1, reference numeral 11 denotes a driving member, and the driving member 11 is made of an elastic member. Reference numeral 21 denotes a taper screw, the taper screw 21 is a male screw that has a taper shape along an axis direction of the screw. In the taper screw 21 of the present embodiment, similarly to a general taper screw for a pipe, a screw is formed on a conical surface and a diameter of the screw changes in accordance with the movement of the screw in the axis direction.

The driving member 11 is provided with a female screw 12 so as to penetrate the driving member 11. The driving member 11 is made of an elastic member elastically deformable in all or a part around the female 12.

The driving apparatus 20a shown in FIG. 1A is a driving apparatus where a taper screw 21 is screwed into the driving member 11 (the female screw 12). A straight screw may also be used as a female screw 12 provided at the driving member 11. However, in order to make a contact state stable when screwing the taper screw 21 (male screw) into the female screw 12, the female screw 12 having a taper shape is preferably applied so as to fit the taper screw 21.

As shown in FIG. 1B, one surface (a lower surface) of the driving member 11 is a fixed surface 13. A position of the fixed surface 13 is always fixed regardless of a moving amount of the taper screw 21. The other surface (an upper surface) of the driving member 11 is a driven surface 14. When the taper screw 21 rotates in a clockwise direction while being screwed into the female screw 12, the taper screw 21 moves in an X axis direction (a direction of an axis AX) to move to a position indicated by a dotted line 211. Such a movement of the taper screw 21 enables the driven surface 14 to move in a Z axis direction (an upward direction) indicated by an arrow to move to a position indicated by a dotted line 141.

In other words, the driving member 11 moves the taper screw 21 in the axis direction of the taper screw 21 while screwing the taper screw 21 into the female screw 12 to displace the member to be driven in a direction orthogonal to the axis direction of the taper screw 21. In the embodiment, the words of “a direction orthogonal to” include a direction which is considered as a substantially orthogonal direction in addition to a strictly orthogonal direction.

In the driving apparatus 20a, the female screw 12 is provided so as to penetrate the driving member 11. The taper screw 21 is screwed into the penetrated female screw 12. Therefore, before and after the movement of the taper screw 21 by the rotation of the taper screw 21, the contact region (contact area between the female screw 12 and the taper screw 21) in the axis direction (X axis direction) that is a traveling direction of the taper screw 21 does not change. Accordingly, when the taper screw 21 rotates, the displacement of the driven surface 14 of the driving member 11 in the X axis direction that is an undesirable direction is small. Thus, according to the driving apparatus of the present embodiment, a highly-accurate positioning drive can be performed.

In order to reduce the displacement of the driving member 11 in a Y axis direction (a direction perpendicular to a cross section shown in FIG. 1) that is a direction different from the driving direction (Z axis direction), it is preferable that each component of the driving apparatus 20a is provided symmetrically with respect to a cross section shown in FIG. 1B.

### Embodiment 2

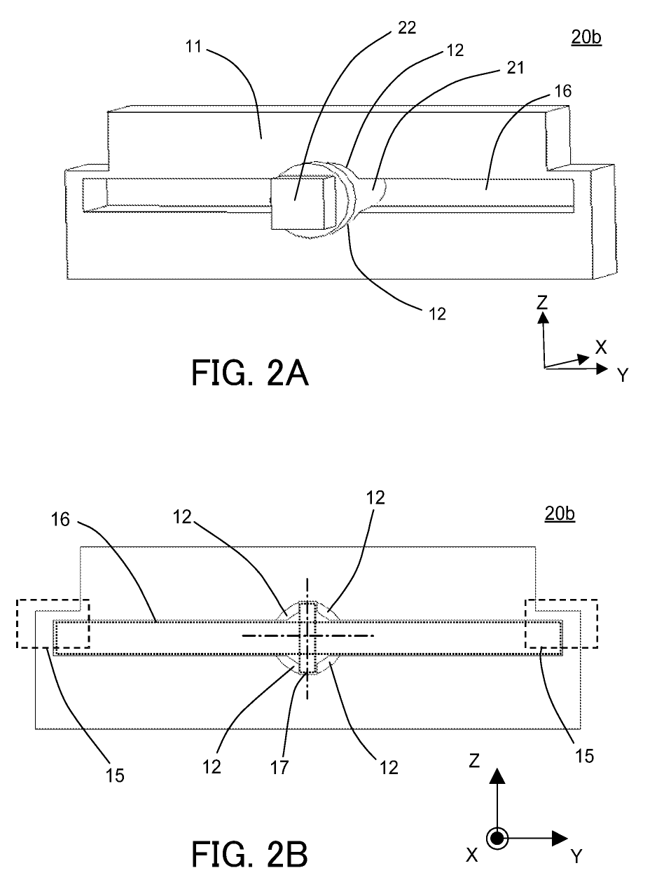

Next, Embodiment 2 of the present invention will be described. FIGS. 2A and 2B are schematic configuration diagrams of a driving apparatus in the present embodiment.

Specifically, FIG. 2A is a perspective view of a driving apparatus 20b, and FIG. 2B is an elevation view of the driving apparatus 20b. FIG. 2B shows a state where a taper screw 21 is screwed into a driving member 11 (a female screw 12). On the other hand, FIG. 2B shows a state where the taper screw 21 is not screwed into the driving member 11.

As shown in FIGS. 2A and 2B, the driving member 11 (inner circumference of the female screw 12) is provided with a cutting portion 16. The cutting portions 16 and 17 penetrate in an axis direction of the female screw 12. Therefore, the inner circumference of the female screw 12 is separated into a plurality of areas (for example four areas) so that the inner circumference is discontinuous.

The cutting portions 16 and 17 provided at the inner circumference of the female screw 12 can be penetrated in parallel to the axis direction (X axis direction) of the female screw 12. Instead of this, when the female screw 12 has a taper shape, the cutting portion may be formed so as to have a shape remaining an edge line along a conical surface that is the inner circumference of the female screw 12. In FIG. 2A, a rotational adjustment portion 22 of the taper screw 21 has a shape cut in four directions, but the rotational adjustment portion 22 can have an arbitrary shape which fits into a tool used for the adjustment.

As shown in FIG. 2B, the driving member 11 is provided with a cutting portion 16 where a Y axis direction is a longitudinal direction. An elastic deformation portion 15 is formed in the driving member 11 at a position distant from the female screw 12. The elastic deformation portion 15 is deformed by the rotation of the taper screw 21.

In the driving apparatus 20b of the present embodiment, because the elastic deformation portion 15 is disposed away from the female screw 12, a reaction force to the taper screw 21 generated by the elastic deformation of the elastic deformation portion 15 decreases. Further, because a stress of the elastic deformation portion 15 decreases in accordance with the decrease of the stress to the taper screw 21, a potential of the displacement of the driving apparatus, which is limited by a permissible stress of a material, is able to be increased.

FIG. 2B shows two cutting portions 16 and 17, but the number and the shape of the cutting portions penetrating in the axis direction can be arbitrarily constituted.

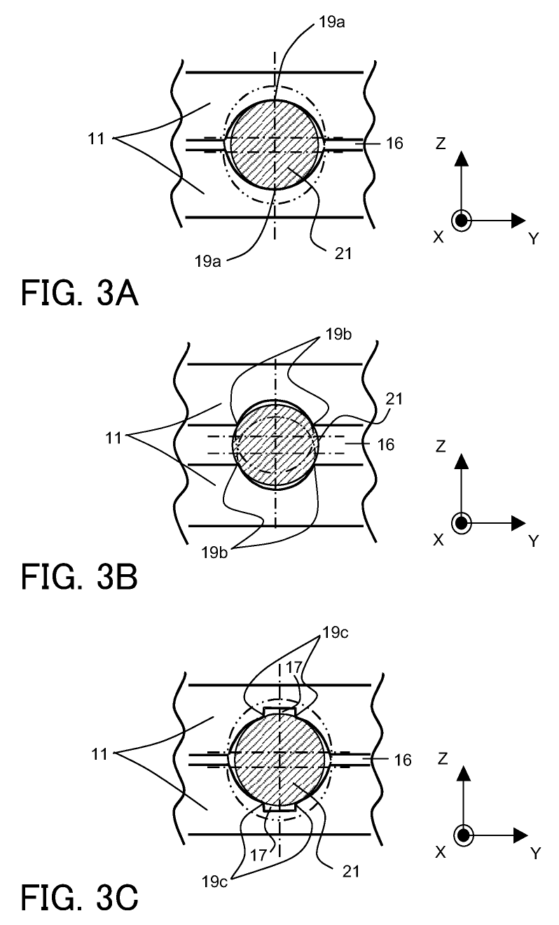

FIGS. 3A to 3C are diagrams showing a relationship between diameters of the taper screw 21 and the female screw 12 in the present embodiment. As shown in FIGS. 3A to 3C, contact positions of these screws are different depending on the relation of the diameters of the taper screw 21 and the female screw 12. The driving member 11 shown in FIGS. 3A and 3B is provided with only one cutting portion 16.

FIG. 3A shows a case where the diameter of the taper screw 21 that is a male screw is smaller than that of the female screw 12. In this case, the taper screw 21 and the female screw 12 come into contact with two points (contact points 19a). On the other hand, FIG. 3B shows a case where the diameter of the taper screw 21 that is a male screw is greater than that of the female screw 12. In this case, the taper screw 21 and the female screw 12 come into contact with four points of edge lines formed by the cutting portion 16 (contact points 19b). In each case, as the diameter of the taper screw 21 increases by the rotation of the taper screw 21, the driving member 11 is displaced in a direction where a width of the cutting portion 16 is enlarged.

FIG. 3C is a diagram showing a contact position of the taper screw 21 and the female screw 12 in a case where the cutting portion 17 shown in FIG. 2B is provided in the driving member 11 in the same state as that of FIG. 3A.

In FIG. 3C, the taper screw 21 and the female screw 12 come into contact with four points of edge lines formed by the cutting portions 17 (contact points 19c). Thus, when the contact is performed at four points, a position in a Y axis direction of the taper screw 21 with respect to the driving member 11 can be stabilized as compared with the case where the contact is performed at two points.

In the driving apparatus of the present invention, as shown in FIGS. 3A and 3B, there are two different contact states in accordance with the relation of the sizes of the taper screw 21 and the female screw 12. As a range of use of the driving apparatus, any one of the contact states can only be used. Both two contact states can also be used with reference to a predetermined rotation position of the taper screw 21 where the relation of the diameter sizes of the screws change.

However, when the drive is performed at the contact points of FIG. 3B, a comparative large influence of the displacement in a driving direction caused by the change of the contact position on the female screw 12 is exerted because the diameter of the taper screw 21 changes. Therefore, in view of a driving accuracy, the drive is preferably performed at contact points of FIG. 3A.

When the female screw 12 penetrating the driving member 11 is processed, a central axis of the penetrating female screw 12 is fixed. Even if the cutting portions 16 and 17 are provided at the inner circumference of the processed female screw 12, a center of each inner diameter of the female screw 12 which is discontinuous in a circumferential direction is still in a coincident state. Subsequently, when the taper screw 21 is screwed into the female screw 12 whose inner diameter centers are coincident with each other to displace the driving member 11, a state shown in FIG. 3B is obtained.

On the other hand, in order to obtain a driving apparatus usable in the state shown in FIG. 3A, it is necessary that the inner diameters of the female screw 12 discontinuous in the circumferential direction are close and that centers of the inner diameters is not in a coincident state. The configuration for realizing the state will be described in Embodiment 3 as follows.

### Embodiment 3

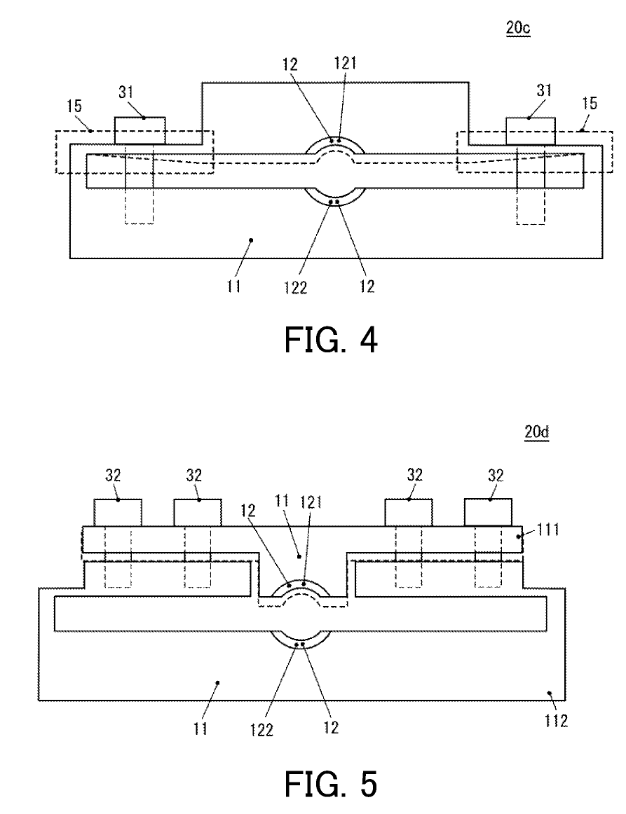

Next, Embodiment 3 of the present invention will be described. FIG. 4 is a schematic configuration diagram of a driving apparatus in the present embodiment. FIG. 4 shows an elevation view of a driving apparatus 20c in a state where a taper screw 21 is not screwed into a driving member 11.

As shown in FIG. 4, the driving apparatus 20c of the present embodiment is provided with an adjustment screw 31 (an adjustment device) to deform an elastic deformation portion 15 of the driving member 11. The adjustment screw 31 applies a forced deformation or an external force to the driving member 11. When the forced deformation or the external force is applied to the driving member 11 (the elastic deformation portion 15) to deform the driving member 11, an upper side female screw portion 121 and a lower side female screw portion 122 of a female screw 12 discontinuous in a circumferential direction (inner circumferences of the separated female screws) can be close to each other (see dotted lines). Thus, the centers of the inner circumferences (inner diameters) of the separated female screws 12 are displaced each other and are not coincident.

When the driving member 11 is deformed so that the upper side female screw portion 121 and the lower side female screw portion 122 can be close to each other, both elastic deformation and plastic deformation may be used.

When the plastic deformation is used in the driving apparatus 20c shown in FIG. 4, the adjustment screw 31 is loosened or unscrewed after the elastic deformation portion 15 is deformed until the plastic deformation is generated by the adjustment screw 31. In this case, the upper female screw portion 121 and the lower female screw portion 122 of the female screw 12 are close to each other due to the generated plastic deformation. When the plastic deformation is used, a member used for the deformation can be removed after the deformation. Therefore, the size of the driving apparatus can be reduced and the number of components can also be reduced.

In the present embodiment, as an adjustment device for deforming the driving member 11, the adjustment screw 31 is used as shown in FIG. 4. The present embodiment is not limited to this, but another adjustment device such as a precompression screw may also be used as long as the device is able to apply the forced deformation or the external force to the driving member 11.

The adjustment screw 31 of the present embodiment deforms the elastic deformation portion 15 which deforms at the time of inserting the taper screw 21 (at the time of driving the driving apparatus 20c), but the present invention is not limited to this. The deforming portion of the driving member 11, which moves the upper side female screw portion 121 and the lower side female screw portion 122 closer to each other, may also be provided at a position different from the elastic deformation portion 15 at the driving time.

### Embodiment 4

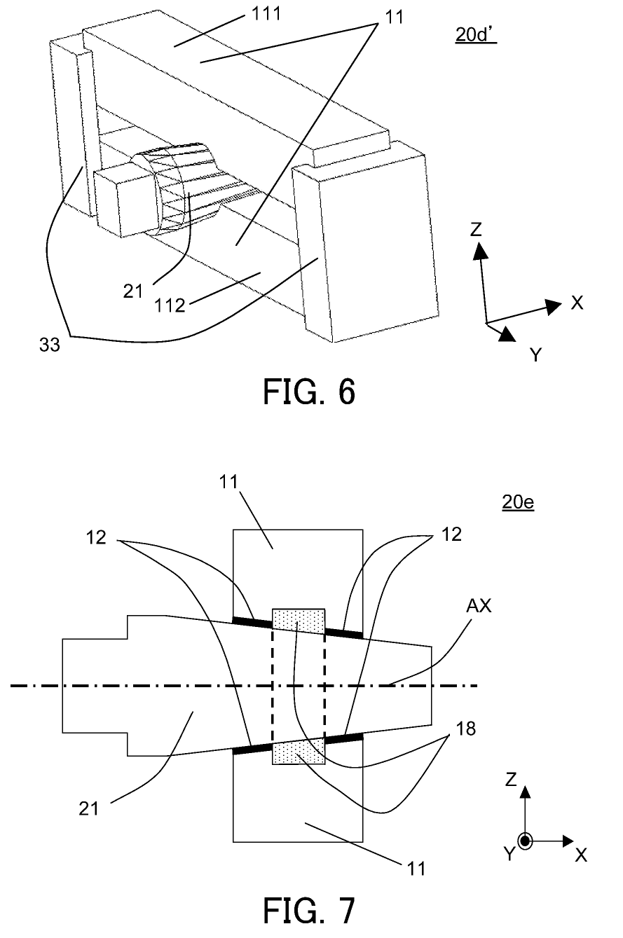

Next, Embodiment 4 of the present invention will be described. FIGS. 5 and 6 are schematic configuration diagrams of a driving apparatus in the present embodiment.

Specifically, FIG. 5 shows an elevation view of a driving apparatus 20d in a state where a taper screw 21 is not screwed into a driving member 11. FIG. 6 shows a perspective view of a driving apparatus 20d′ in which a guide defining a deformation direction of the driving member is provided.

As shown in FIG. 5, in the driving apparatus 20d of the present embodiment, the female screw 12 has discontinuous inner circumferences, and an upper side female screw portion 121 and the lower side female screw portion 122 are close to each other (see dotted lines) by using a fixing bolt 32. Therefore, the centers of the inner circumferences (inner diameters) of the upper side female screw portion 121 and the lower side female screw portion 122 are displaced each other and are not coincident.

The driving member 11 of the present embodiment includes two driving portions 111 and 112 which are formed so as to separate the inner circumference of the female screw 12. The driving portion 111 is provided with an upper side female screw 121, and the driving portion 112 is provided with a lower side female screw 122. The separated female screws 12 are formed by connecting the driving portions 111 and 112 using the fixing bolt 32. Since the separated driving members 11 (the driving portions 111 and 112) are connected in a state where the inner circumferences of the upper and lower female screws 12 are close to each other, the driving apparatus which is driven at the same contact area as that shown in FIG. 3A can be constituted.

In the present embodiment, as shown in FIG. 5, the fixing bolts 32 are used as connecting devices of the driving portions 111 and 112. The connecting devices are not limited to them, but the driving portions 111 and 112 may also be connected by pin connections, jointing, adhesive bonding, or the like.

FIG. 6 is another embodiment in a case where the driving member 11 is formed by connecting the two driving portions 111 and 112.

In the driving apparatus 20d′ shown in FIG. 6, guides 33 are provided at both sides of separated driving members 11 (driving portions 111 and 112). The guide 33 defines a displacement direction of the driving members 11 (the driving portions 111 and 112). The guides 33 are provided at both sides of the driving member 11 to stably determine a driving direction of the driving members 11 in a Z axis direction, and a taper screw 21 is screwed into separated female screws 12.

When the driving portions 111 and 112 drive an apparatus to be driven, they are used as a fixing portion which fixes one of the driving portions (driving portion 112) to a reference position, and as a movable portion which is capable of driving the other of the driving portion (driving portion 111) by using the taper screw 21.

In the driving apparatus 20d which is formed by screwing the taper screw 21 into the driving member 11, shown in FIG. 5, and the driving apparatus 20d′ shown in FIG. 6, a precompression apparatus (not shown) which applies an external force to the driving direction or a moving direction of the taper screw 21 (an axis direction of the taper screw 21) may also be provided. The precompression apparatus is provided so that the female screw 12 can firmly come into contact with the taper screw 21.

Particularly, in the driving apparatus 20d (FIG. 5) and the driving apparatus 20d′ (FIG. 6) in which the two driving portions 111 and 112 are connected by pin connections, when a diameter of the taper screw 21 which is screwed into the female screw 12 is small, the female screw 12 can not firmly come into contact with the taper screw 21. This becomes strongly apparent in a case where a moving direction of the taper screw 21 (an axis direction of the taper screw 21) is not coincident with a direction of gravitational direction.

Even if the contact between the female screw 12 and the taper screw 21 is released by using the precompression apparatus of the present embodiment, the contact between these screws is maintained by applying an external force sufficient to move the separated female screws 12. Therefore, according to the configuration of the present embodiment, the taper screw 21 is able to stably move in both positive and negative directions.

### Embodiment 5

Next, Embodiment 5 of the present invention will be described. FIG. 7 is a schematic configuration diagram of a driving apparatus in the present embodiment.

Specifically, FIG. 7 is a cross-sectional view of a driving apparatus 20e which is cut in a plane of a Z axis direction that is a driving direction of the driving apparatus 20e and an X axis direction that is a moving direction of the taper screw 21 (a direction orthogonal to a Y axis direction) at an axis center of a taper screw 21.

In FIG. 1B, a screw portion of the female screw 12 of the driving member 11 (inner circumference of the female screw 12) has been continuous in an axis direction of the taper screw 21. On the other hand, in the present embodiment, as shown in FIG. 7, screw portions of the female screw 12 are separated in the axis direction by a clearance portion 18.

In FIG. 1B, if a screw thread is ideally formed, a contact area in an axis direction of the female screw 12 of the driving member 11 with respect to the taper screw 21 does not change. Therefore, the displacement of the driving member 11 in the axis direction that is a displacement in an undesirable direction is small. However, there is a manufacturing error in a diameter of a taper angle or a diameter of each screw thread. Therefore, a tilt around the Y axis is generated in the driving member 11 to generate a displacement in the axis direction of the taper screw 21 in accordance with the movement by the rotation of the taper screw 21.

When there is a manufacturing error in the screw portion, a precompression having at least predetermined value needs to be applied to the screw portion in order to contact all screw portions to average the manufacturing error. The clearance portion 18 shown in FIG. 17 maintains a contact space of the axis direction (the X axis direction) which effects on the tilt of the screw portion around the Y axis direction to reduce the contact area of the screw portion to be able to easily obtain at least the predetermined value.

Therefore, according to the configuration of the present embodiment, the displacement in the axis direction of the screw portion of the driving apparatus caused by the manufacturing error can be reduced.

### Embodiment 6

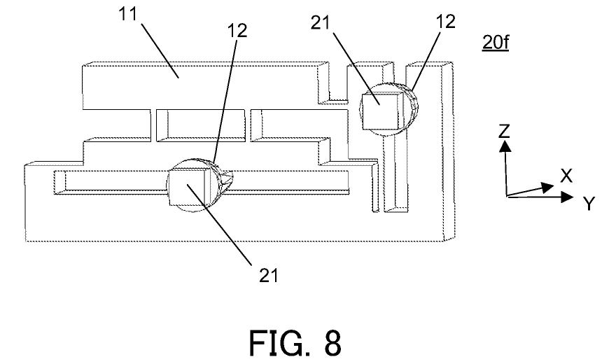

Next, Embodiment 6 of the present invention will be described. FIG. 8 is a schematic configuration diagram of a driving apparatus in the present embodiment, which is a perspective view of the driving apparatus.

As shown in FIG. 8, a driving apparatus 20f of the present embodiment is provided with two female screws 12 penetrating a driving member 11, and a taper screw 21 is screwed into each of the two female screws 12.

In the driving apparatus 20f of the present embodiment, moving directions of the driving member 11 along with the rotation of the two taper screws 21 are different from each other. Therefore, according to the present embodiment, the member to be driven is able to be driven in biaxial translation directions of the Y axis direction and Z axis direction.

In the present embodiment, a rough micromotion adjustment can also be performed if taper angles different from each other are set to the two taper screws 21 and the driving direction of the driving member 11 along with the rotation of the two taper screws 21 are set to be the same. When at least two taper screws 21 are provided, the degree of freedom of the driving direction or the driving amount can be improved as compared with the driving apparatus where only one taper screw 21 is provided.

In the driving apparatus of each of the above embodiments, the driving direction of the driving member using the taper screw is a direction orthogonal to the axis direction of the taper screw (a moving direction). Therefore, a driving apparatus with a small size of the taper screw 21 in the moving direction as compared with a size of the taper screw 21 in the axis direction can be easily constituted.

In the driving apparatus of each of the above embodiment, the screw diameter of the taper screw is changed by the rotation of the taper screw. Thus, the driving member is elastically deformed, and the inner diameter of the female screw penetrating the driving member is displaced. In this case, the contact region (contact area) of the taper screw and the female screw is driven in a constant state. Therefore, the possibility that the driving member is displaced in an undesirable direction is low. Further, since there is a cutting portion formed in the driving member, the elastic deformation portion of the driving member can be away by at least predetermined distance from the female screw. Therefore, an adjustment amount of the elastic deformation can be increased.

According to each of the above embodiments, a small size driving apparatus capable of adjusting a position of a member to be driven with high accuracy can be provided.

The driving apparatus of each of the embodiments can be used, for example for adjusting an optical element in an optical barrel (a driven apparatus). In the optical barrel, a plurality of optical elements are stacked along an optical axis direction, and adjustments of a position, a tilt, and an eccentricity in the optical axis direction of each optical element in the optical barrel need to be performed. When the plurality of optical elements are adjustable in order to improve the adjustment degree of freedom of the optical performance, the optical element adjusting apparatus is particularly needs to reduce the size in the optical axis direction.

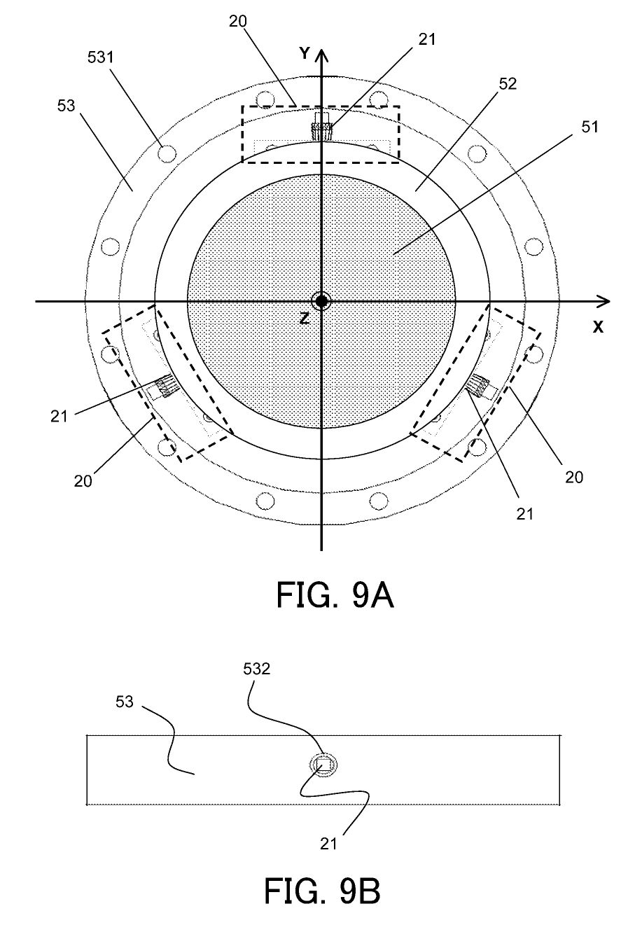

FIGS. 9A and 9B are schematic configuration diagrams of an optical element adjusting apparatus in the present embodiment. Specifically, FIGS. 9A and 9B are a plan view and a side view of the optical element adjusting apparatus in the present embodiment, respectively.

As shown in FIGS. 9A and 9B, the optical element adjusting apparatus of the present embodiment includes three driving apparatuses 20 of any of the above embodiments which are arranged at angles differing from one another by 120 degrees considering the optical element 51 as a center. The present embodiment is not limited to this, but the optical element 51 may be adjustable to a desired position by using at least one driving apparatus 20 of any of the above embodiments.

In FIG. 9A, reference numeral 52 denotes an intermediate holding member which is held by the three driving apparatuses 20. Reference numeral 53 denotes a cylinder holding member for fixing the driving apparatuses 20. In the vicinity of the outer circumference of the cylinder holding member 53, joint holes 531 that are screw holes or through holes for connecting the upper and lower optical unit are provided.

As shown in FIG. 9B, even if the optical element adjusting apparatus is connected with the upper and lower optical unit, in order to be able to adjust the taper screw 21 of the driving apparatus 20, an outer wall of the cylinder holding member 53 is provided with an adjustment hole 532. The inner taper screw 21 can be seen from the adjustment hole 532. Therefore, a rotational adjustment of the taper screw 21 can be performed by using a tool or the like. The adjustment hole 532 provided in the cylinder holding member 53 may also be covered by a lid when adjusting the taper screw 21 is not necessary.

In FIG. 9A, each of the three driving apparatuses 20 is driven in an optical axis direction by rotating the taper screw 21 to move it in a direction orthogonal to the optical axis direction (Z axis direction). Therefore, in the optical element adjusting apparatus of the present embodiment, the position adjustment of the optical element 51 can be performed in the optical axis direction and around biaxial directions orthogonal to the optical axis direction (around the X and Y axes). Thus, the optical element adjusting apparatus of the present embodiment is configured so as to be able to adjust the position and the tilt in the optical axis direction of the optical element by using the three driving apparatuses.

In the optical element adjusting apparatus of the present embodiment, as a method for rotationally adjusting the taper screw 21, there is a manual adjustment using a tool, an adjustment based on a signal input obtained by an attached actuator, or the like, and any appropriate method is selectively used.

The optical element adjusting apparatus of the present embodiment is provided for adjusting a position of the optical element 51, and performs an adjustment of the optical element 51 so as to measure the optical performance to be able to obtain a desired optical performance. The optical element adjusting apparatus of the present embodiment can also be provided with a position detector (not shown) which detects a position of the intermediate holding member 52 or the optical element 51. In this case, the optical element adjusting apparatus is capable of adjusting the optical element 51 while referring to the displacement detected by the position detector.

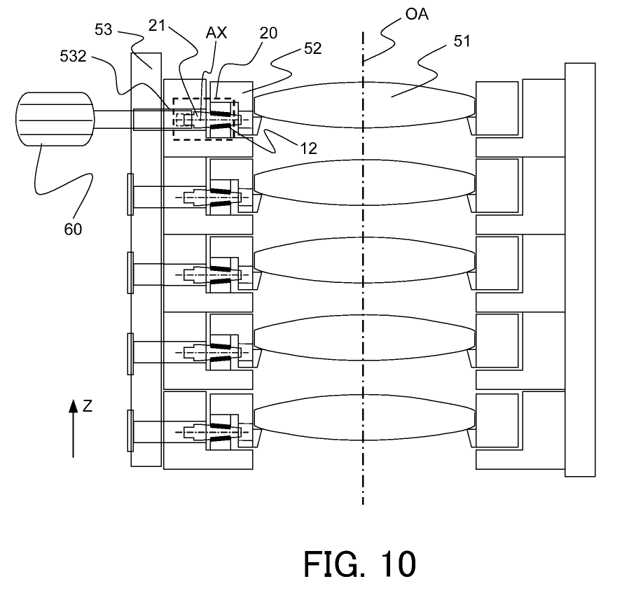

FIG. 10 is a cross-sectional view of an optical barrel having a plurality of optical element adjusting apparatuses of the present embodiment.

As shown in FIG. 10, a direction of an axis AX of the taper screw 21 (an axis direction) and a direction of an optical axis OA parallel to a Z axis direction (an optical axis direction) are orthogonal to each other. A driving direction of the driving apparatus 20 (an upward direction in FIG. 10) is coincident with the direction of the optical axis OA.

In the optical barrel of the present embodiment, the position adjustment of the optical element 51 is performed by rotating the taper screw 21 through the adjustment hole 532 opened on the side wall. Reference numeral 60 denotes an adjustment tool for rotating the taper screw 21. When a joint function is provided to the adjustment tool 60, a force other than a rotational force applied to the taper screw 21 can be reduced.

In the optical barrel including a plurality of optical element adjusting apparatuses of the present embodiment, the inner optical element 51 can be adjusted through the side wall of the optical barrel. Therefore, the adjustment of the optical performance can be performed in a short time without taking apart the optical barrel for adjusting the optical performance.

The optical element adjusting apparatus of the present embodiment can be used for an exposure apparatus which performs a reduced projection of a pattern on a reticle onto a wafer by using light having a wavelength of ultraviolet range.

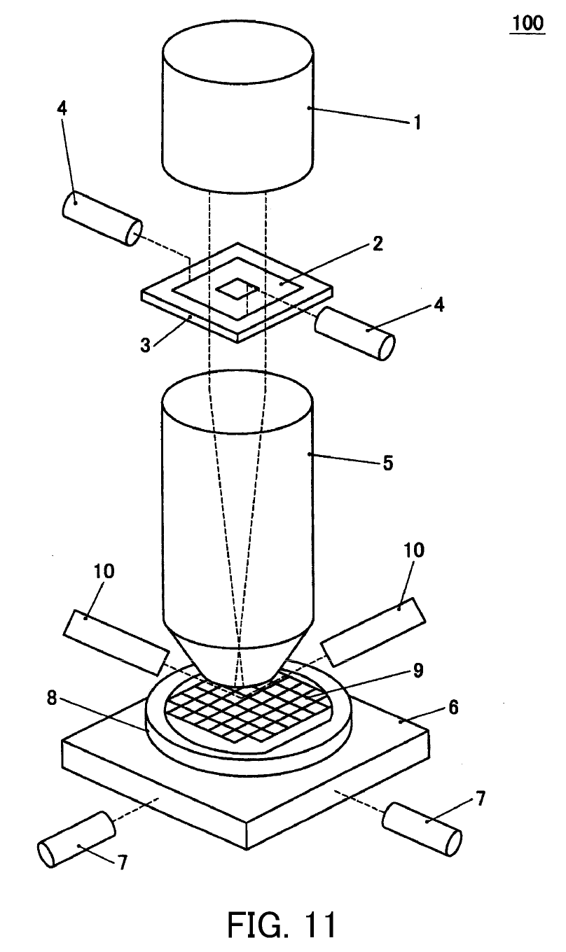

Next, a configuration of an exposure apparatus which includes the optical element adjusting apparatus of the present embodiment (the driving apparatus of each of the above embodiments) will be described. FIG. 11 is a schematic configuration diagram of an exposure apparatus 100 in the present embodiment. The exposure apparatus 100 is an exposure apparatus which exposes a pattern of an original plate onto a substrate.

In FIG. 11, reference numeral 1 denotes an illumination apparatus. The illumination apparatus 1 constitutes an illumination optical system which illuminates a pattern of a reticle (an original plate) by using light from a light source and includes the light source and a shutter (not shown) inside it. Reference numeral 2 denotes a reticle (an original plate). A circuit pattern is depicted on the reticle 2. When the light is illuminated onto the reticle 2 using the illumination apparatus 1, the circuit pattern formed on the reticle 2 is projected onto the wafer 9.

Reference numeral 3 denotes a reticle stage. The reticle stage 3 is provided for moving while mounting the reticle 2 on it. Reference numeral 4 denotes a reticle position measuring portion. The reticle position measuring portion 4 measures a position of the reticle 2 mounted on the reticle stage 3 (a position of the reticle stage 3).

Reference numeral 5 denotes a projection optical system. The projection optical system 5 includes a plurality of optical elements (lenses) in the optical barrel, and projects the pattern on the reticle 2 onto the wafer (substrate).

Reference numeral 6 denotes a wafer stage. The wafer stage 6 mounts the wafer 9 (substrate) and moves in an in-plane direction (X and Y directions).

Reference numeral 7 denotes a laser interferometer. The interferometer 7 measures a position of the wafer stage 6. Reference numeral 8 denotes a wafer chuck. The wafer chuck 8 absorbs and holds the wafer 9. Reference numeral 10 denotes an autofocus unit. The autofocus unit 10 measures a focal position of the wafer 9.

In the exposure apparatus 100, highly-accurate adjustments of positions of the plurality of optical elements constituting the projection optical system 5 are required. A large optical barrel is used for the projection optical system 5. Therefore, long processes are necessary in order to take apart the optical barrel constituting the projection optical system 5 to perform an adjustment and assemble the disassembled optical barrel again. Therefore, according to the present embodiment, the optical performance can be adjusted without taking apart the optical barrel of the projection optical system 5.

A device (a semiconductor integrated circuit device, a liquid crystal display device, or the like) is manufactured by a process of exposing a substrate (a wafer, a glass plate, or the like) which is coated by a photosensitizing agent using the exposure apparatus in any one of the above embodiments, a process of developing the substrate, and other well-known processes.

According to the present embodiment, small-sized driving apparatus and exposure apparatus capable of adjusting a position of an optical element with high accuracy can be provided. Further, a highly-accurate device manufacturing method can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-298788, filed on Nov. 21, 2008, which is hereby incorporated by reference herein in its entirety.

What is claimed is:

1. A driving apparatus which adjusts a position of a member to be driven, the driving apparatus comprising:
a driving member connected with the member to be driven and made of an elastic member;
a female screw provided so as to penetrate the driving member; and
a taper-shaped male screw configured to be screwed into the female screw,
wherein the driving member is provided with a cutting portion which penetrates in an axis direction of the female screw so that an inner circumference of the female screw is discontinuous, and
wherein the driving member is configured to move in an axis direction of the male screw in a state where the male screw is screwed into the female screw to displace the member to be driven in a direction orthogonal to the axis direction of the male screw.

2. A driving apparatus according to claim 1, further comprising an adjustment device configured to apply at least one of a forced displacement and an external force to the driving member,
wherein the inner circumference of the female screw is separated into a plurality of regions by the cutting portion, and
wherein the adjustment device is configured to apply the at least one of the forced displacement and the external force to the driving member so that the inner circumferences of the separated female screws are close to each other and centers of the inner circumferences of the female screws are displaced from each other.

3. A driving apparatus according to claim 1,
wherein the driving member includes at least two driving portions which are formed so as to separate the inner circumference of the female screw, and
wherein the at least two driving portions are connected so as to form separated female screws.

4. A driving apparatus according to claim 3,
wherein the driving member is provided with a guide defining a displacement direction of the driving portion.

5. A driving apparatus according to claim 1, further comprising a precompression apparatus configured to apply an external force to bring the female screw into contact with the male screw.

6. A driving apparatus according to claim 1,
wherein the driving member is provided with at least two female screws, and
wherein the taper-shaped male screw is screwed into each of the at least two female screws.

7. An exposure apparatus which exposes a pattern on an original plate onto a substrate, the exposure apparatus comprising:
an illumination optical system configured to illuminate the original plate by using light from a light source; and
a projection optical system configured to project the pattern on the original plate onto the substrate,
wherein the projection optical system includes an optical element and a driving apparatus configured to adjust a position of the optical element in an optical axis direction,
wherein the driving apparatus includes a driving member made of an elastic member, a female screw provided so as to penetrate the driving member, and a taper-shaped male screw configured to be screwed into the female screw,
wherein the driving member is provided with a cutting portion which penetrates in an axis direction of the female screw so that an inner circumference of the female screw is discontinuous, and
wherein the driving member is configured to move in an axis direction of the male screw in a state where the male screw is screwed into the female screw to displace the optical element in a direction orthogonal to the axis direction of the male screw.

8. An exposure apparatus according to claim 7,
wherein the driving apparatuses are disposed at least at three areas of the optical element, and
wherein a position and a tilt of the optical element in the optical axis direction is adjustable by using the driving apparatuses disposed at least at the three areas.

9. A device manufacturing method comprising the steps of:
exposing a substrate using an exposure apparatus; and
developing the exposed substrate,
wherein the exposure apparatus is configured to expose a pattern on an original plate onto a substrate, the exposure apparatus comprising:
an illumination optical system configured to illuminate the original plate by using light from a light source; and
a projection optical system configured to project the pattern on the original plate onto the substrate,
wherein the projection optical system includes an optical element and a driving apparatus configured to adjust a position of the optical element in an optical axis direction,
wherein the driving apparatus includes a driving member made of an elastic member, a female screw provided so as to penetrate the driving member, and a taper-shaped male screw configured to be screwed into the female screw,
wherein the driving member is provided with a cutting portion which penetrates in an axis direction of the female screw so that an inner circumference of the female screw is discontinuous, and
wherein the driving member is configured to move in an axis direction of the male screw in a state where the male screw is screwed into the female screw to displace the optical element in a direction orthogonal to the axis direction of the male screw.
